(19) United States
(12) Patent Application Publication
(10) Pub. No.: US 2013/0133914 A1
(43) Pub. Date: May 30, 2013

(54) HOUSING OF ELECTRONIC DEVICE AND METHOD FOR MANUFACTURING THE SAME

(71) Applicants: YAN-SHUANG LV, Shenzhen City (CN); CHIA-MING HSU, Tu-Cheng (TW); SHENG-HSIANG SU, Tu-Cheng (TW)

(72) Inventors: YAN-SHUANG LV, Shenzhen City (CN); CHIA-MING HSU, Tu-Cheng (TW); SHENG-HSIANG SU, Tu-Cheng (TW)

(21) Appl. No.: 13/651,622

(22) Filed: Oct. 15, 2012

(30) Foreign Application Priority Data
Nov. 24, 2011 (CN) 201110378242.0

(51) Int. Cl. H05K 5/02; C23C 28/02; B05D 3/10; B05D 3/00; B05D 1/36; B05D 3/12

(52) U.S. Cl. 174/50; 427/405; 427/560; 427/309; 427/328; 427/406; 205/184

(57) ABSTRACT

A housing of electronic device includes a metallic substrate, a copper layer formed on the metallic substrate, and a heat dissipation layer formed on the copper layer. A method for manufacturing the housing is also provided.

### BACKGROUND

1. Technical Field

The present disclosure generally relates to housings, and particularly, to a housing of an electronic device and a method for manufacturing the housing.

2. Description of the Related Art

In order to prevent dust from contaminating the interior of an electronic device, a housing of the electronic device will not define holes for heat dissipation. With the trend towards miniaturization the interior space of the housing has become smaller and smaller. Thus, there is not enough space to install a heat dissipation module, such as a fan, in the housing. Thus, it is inconvenient to dissipate the heat from the interior of the electronic device to the outside of the electronic device, and this results in an increase in the failure rate of the electronic device.

Therefore, there is room for improvement within the art.

### BRIEF DESCRIPTION OF THE DRAWING

The components in the drawings are not necessarily drawn to scale, the emphasis instead placed upon clearly illustrating the principles of the present disclosure. Moreover, in the drawings, like reference numerals designate corresponding parts throughout the several views.

FIG. 1 is a partial, cross-sectional view of an embodiment of a housing of an electronic device.

FIG. 2 is a flowchart of a method for manufacturing the housing of the electronic device of FIG. 1.

### DETAILED DESCRIPTION

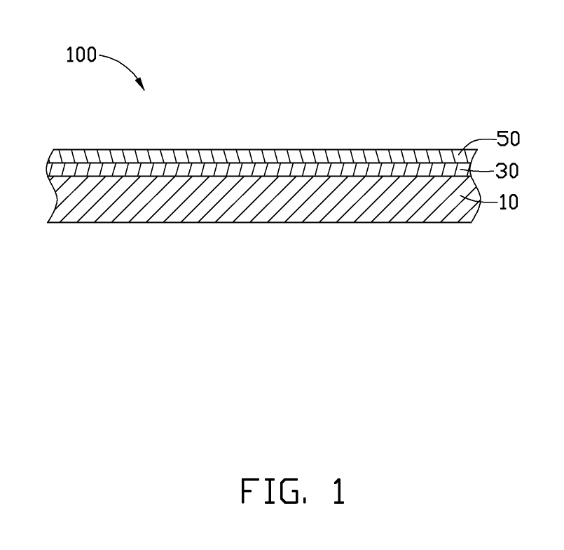

Referring to FIG. 1, an embodiment of a housing 100 of an electronic device is shown. The housing 100 includes a metallic substrate 10, a copper layer 30 formed on the metallic substrate 10, and a heat dissipation layer 50 formed on the copper layer 30. In the illustrated embodiment, the metallic substrate 10 is made of magnesium alloy. It is to be understood that, the metallic substrate 10 can be made of aluminium, zinc, aluminium alloy, or zinc alloy, which is excellent in heat dissipation performance.

The copper layer 30 is formed on the metallic substrate 10 by electroplating. The thickness of the copper layer 30 may be in a range from about 1 micrometer (μm) to about 40 μm. It is to be understood that, the copper layer 30 can be formed by vacuum deposition, sputtering, or ion deposition.

The heat dissipation layer 50 is coated on the copper layer 30 by painting with a heat dissipation paint. The heat dissipation paint includes a heat dissipation component, a film-forming component, and a solvent. The heat dissipation component is selected from a group consisting of boron nitride (BN), silicon carbon (SiC), and aluminium nitride (AlN). The film-forming component is selected from a group consisting of aluminum oxide (Al₂O₃), and silicon oxide (SiO₂). The solvent is selected from a group consisting of isopropyl alcohol, alcohol, and deionized water. The thickness of the heat dissipation layer 50 is in a range from about 5 μm to about 30 μm.

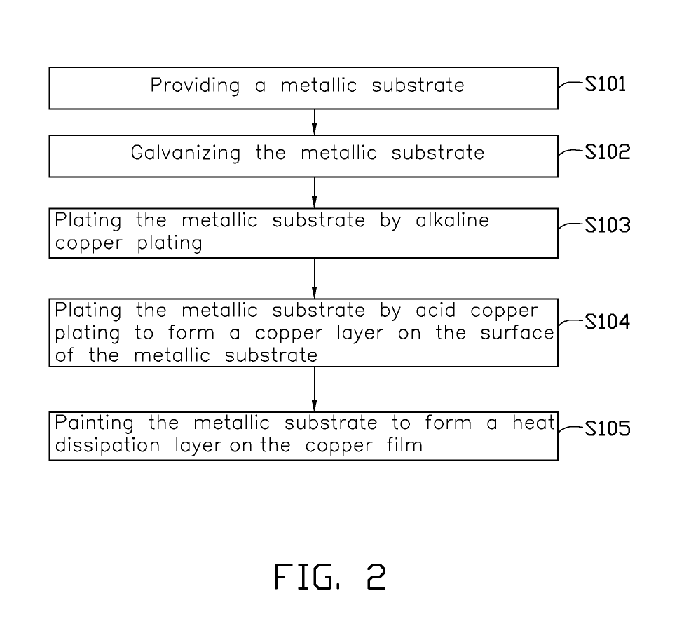

Also referring to FIG. 2, an embodiment of a method for manufacturing the housing 100 is illustrated as follows.

In step S101: a metallic substrate 10 is provided. In the illustrated embodiment, the metallic substrate 10 is made of magnesium alloy. At least one of ultrasonic cleaning, etching, and activating to remove contaminants, such as grease, oxide, or dirt, may be used to pretreat the metallic substrate 10.

In step S102: the metallic substrate 10 is treated by galvanizing. In this step, temperature is controlled to be in a range from about 70° C. to about 80° C. Hydrogen ion concentration (PH) is controlled to be in a range from about 10.2 to about 10.4. Galvanizing time is controlled to be in a range from about 3 minutes to about 10 minutes, and the galvanizing solution contains 30 g/L to 50 g/L ZnSO₄.7H₂O, 5 g/L to 10 g/L Na₂CO₃, 80 g/L to 120 g/L Na₄P₂O₇, and 3 g/L-5 g/L LiF. LiF can be replaced by NaF. In an alternative embodiment, the metallic substrate 10 treated by galvanizing may be treated by galvanizing again to form a good zinc coating on the surface of the metallic substrate 10.

In step S103: the metallic substrate 10 is treated by alkaline copper plating. In this step, temperature is controlled to be in a range from about 45° C. to about 60° C., and PH is controlled to be in a range from about 9.6 to about 10.4. A copper board is connected to anode, and the metallic substrate 10 is connected to cathode. The plating solution contains 38 g/L to 42 g/L CuCN, 65 g/L to 72 g/L KCN, 28.5 g/L to 31.5 g/L KF. The initial current density is 5 A/dm² to 10 A/dm², and the operating current density is 1 A/dm² to 2.5 A/dm².

In step S104: the metallic substrate 10 is treated by acid copper plating to form a copper layer 30 on the surface of the metallic substrate 10. In this step, temperature is controlled to be in a range from about 20° C. to about 30° C. A copper board is connected to anode, and the metallic substrate is connected to cathode. The plating solution contains 200 g/L to 220 g/L CuSO₄.5H₂O, 30 ml/L to 40 ml/L H₂SO₄, 80 mg/L to 150 mg/L Cl⁻, 0.4 ml/L to 0.6 ml/L brightening agent, and 0.4 ml/L to 0.6 ml/L leveling agent. The cathode current density is 5 A/dm² to 10 A/dm², and the anode current density is 1 A/dm² to 2.5 A/dm². The thickness of the copper layer 30 may be about 1 μm to about 40 μm.

In step S105: the metallic substrate is treated by painting to form a heat dissipation layer 50 on the copper layer 30. The heat dissipation layer 50 is formed by painting heat dissipation paint on the copper layer 30. The heat dissipation paint includes a heat dissipation component, a film-forming component, and a solvent. The heat dissipation component is selected from a group consisting of boron nitride (BN), silicon carbon (SiC), and aluminium nitride (AlN). The film-forming component is selected from a group consisting of aluminum oxide (Al₂O₃), and silicon oxide (SiO₂). The solvent is selected from a group consisting of isopropyl alcohol, alcohol, and deionized water. The thickness of the heat dissipation layer 50 is in a range from about 5 μm to about 30 μm.

It is essential for metallic substrate made of reactive metal, such as aluminium, zinc, aluminium alloy, or zinc alloy to form a zinc layer on the metallic substrate by the step 102 before forming the copper layer. In alternative embodiments, the step 102 can be omitted for metallic substrate made of nonreactive metal, such as iron, or stainless steel.

In alternative embodiments, the heat dissipation layer can be a single layer, the heat dissipation layer can also include at least two layers formed by painting different heat dissipation paints, such as a primer, an inter-layer, and a top coating.

A sample of the housing 100 manufactured by the method of this invention is provided. In the sample, the housing 100 is made of magnesium alloy. The manufacturing process of the housing 200 is illustrated as follows.

First, a metallic substrate made of magnesium alloy is provided. Ultrasonic cleaning to remove contaminants, such as grease, oxide, or dirt, pretreats the metallic substrate.

Second, the metallic substrate is treated by galvanizing. In this step, temperature is 75° C., PH is 10.2, galvanizing time is 5 minutes, and the galvanizing solution contains 40 g/L ZnSO₄.7H₂O, 5 g/L Na₂CO₃, 80 g/L Na₄P₂O₇, and 3 g/L LiF.

Third, the metallic substrate is treated by alkaline copper plating. In this step, temperature is 45° C., and PH is 9.6. A copper board is connected to anode, and the metallic substrate is connected to cathode. The plating solution contains 38 g/L CuCN, 65 g/L KCN, 28.5 g/L KF. The initial current density is 5 A/dm², and the operating current density is 2 A/dm².

Fourth, to form a copper layer on the surface of the metallic substrate, the metallic substrate is treated by acid copper plating. In this step, temperature is 25° C. A copper board is connected to anode, and the metallic substrate is connected to cathode. The plating solution contains 200 g/L CuSO₄.5H₂O, 30 ml/L H₂SO₄, 80 mg/L Cl⁻, 0.4 ml/L brightening agent, and 0.4 ml/L leveling agent. The anode current density is 6 A/dm², and the cathode current density is 2.5 A/dm². The thickness of the copper layer is 10 μm.

Fifth, the metallic substrate is treated by painting to form a heat dissipation layer on the copper layer. The heat dissipation layer is formed by painting a heat dissipation paint on the copper layer. The heat dissipation paint contains 30 wt % polyurethane acrylate oligomer, 24 wt % AlN, 10 wt % Al₂O₃, 15 wt % silane coupling agent, and 21 wt % mixed solvent. The thickness of the heat dissipation layer 50 is 15 μm.

A contrast sample of the housing is also provided. The contrast sample is made of magnesium alloy, and the contrast sample is only treated by sandblasting.

The heat dissipation performance of the housing 100 and the contrast sample are tested at a room temperature 30° C. In order to test the heat dissipation performance of the housing 100 and the contrast sample, two heaters 70, 90 are provided. The two heaters 70, 90 are both micro-heaters, which are considered as the electronic elements of the electronic device. The heater 70 is fixed to the center of the housing 100, and the heater 90 is fixed to the center of the contrast sample. The two heaters 70, 90 heat the housing 100 and the contrast sample, respectively, and the output power of each of the two heaters 70, 90 is 1 W. After the temperature of each of the housing 100 and the contrast sample is stable, the test result is recorded in table 1. In the illustrated embodiment, in order to obtain a relatively precise result, the housing 100 selects two testing portions at opposite ends, and the contrast sample selects two testing portions at opposite ends.

TABLE 1
Testing Result

| | Testing Items | | | | | |
|---|---|---|---|---|---|---|
| | | | Sample of Housing 100 | | Contrast Sample | |
| | Heater | Heater | Testing | Testing | Testing | Testing |
| | 70 | 90 | Portion 1 | Portion 2 | Portion 1 | Portion 2 |
| Temperature (° C.) | 40.03 | 38.75 | 30.13 | 30.16 | 32.44 | 32.29 |

| | | | | |
|---|---|---|---|---|
| Average | / | / | 30.15 | 32.37 |
| Temperature (° C.) | | | | |

As seen in table 1, the temperature of the heater 90 is 1.28° C. lower than the temperature of the heater 70. The average temperature of the housing 100 is 2.22° C. lower than the average temperature of the contrast sample, which illustrates that the heat dissipation performance of the housing 100 is at maximum.

The housing 100 includes a copper layer 30 formed on the metallic substrate 10 and a heat dissipation layer 50 formed on the copper layer 30. The copper layer 30 can increase the thermal conductivity of the housing 100, and the heat dissipation layer 50 can radiate heat to the outside of the electronic device. Thus, the heat dissipation performance of the housing 100 is improved.

While the present disclosure has been described with reference to particular embodiments, the description is illustrative of the disclosure and is not to be construed as limiting the disclosure. Therefore, various modifications can be made to the embodiments by those of ordinary skill in the art without departing from the true spirit and scope of the disclosure, as defined by the appended claims.

What is claimed is:

1. A housing of electronic device, comprising:
a metallic substrate;
a copper layer formed on the metallic substrate; and
a heat dissipation layer formed on the copper layer.

2. The housing of claim 1, wherein the thickness of the copper layer is in a range from about 1 μm to about 40 μm.

3. The housing of claim 1, wherein the heat dissipation layer is selected from the group consisting of boron nitride (BN), silicon carbon (SiC), aluminium nitride (AlN), and a combination thereof.

4. The housing of claim 1, wherein the metallic substrate is selected from a group consisting of magnesium alloy, aluminium, zinc, aluminium alloy, and zinc alloy.

5. A method of manufacturing a housing, comprising:
forming a copper layer on the surface of a metallic substrate; and
forming a heat dissipation layer on the copper layer.

6. The method of claim 5, wherein at least one of ultrasonic cleaning, etching, and activating to remove contaminants is used to pretreat the metallic substrate before forming the copper layer.

7. The method of claim 5, wherein the metallic substrate is made of magnesium alloy, the metallic substrate is treated by galvanizing before forming the copper layer.

8. The method of claim 7, wherein in the galvanizing, the temperature of the galvanizing solution is controlled to be in a range from about 70° C. to about 80° C., PH is controlled to be in a range from about 10.2 to about 10.4, the galvanizing time is controlled to be in a range from about 3 minutes to about 10 minutes, and the galvanizing solution contains 30 g/L to 50 g/L ZnSO₄.7H₂O, 5 g/L to 10 g/L Na₂CO₃, 80 g/L to 120 g/L Na₄P₂O₇, and 3 g/L-5 g/L LiF.

9. The method of claim 8, wherein before forming the copper layer, the metallic substrate is treated by alkaline copper plating after being treated by galvanizing.

10. The method of claim 9, wherein, in the alkaline copper plating, the temperature of the plating solution is controlled to be in a range from about 45° C. to about 60° C., PH is controlled to be in a range from about 9.6 to about 10.4, a copper board is connected to anode, the metallic substrate is connected to cathode, the plating solution contains 38 g/L to 42 g/L CuCN, 65 g/L to 72 g/L KCN, 28.5 g/L to 31.5 g/L KF, the initial current density is 5 A/dm² to 10 A/dm², and the operating current density is 1 A/dm² to 2.5 A/dm².

11. The method of claim 9, wherein the metallic substrate is treated by acid copper plating after being treated by alkaline copper plating to form the copper layer on the surface of the metallic substrate.

12. The method of claim 11, wherein in the acid copper plating, the temperature of the plating solution is controlled to be in a range from about 20° C. to about 30° C., a copper board is connected to anode, the metallic substrate is connected to cathode, the plating solution contains 200 g/L to 220 g/L CuSO₄.5H₂O, 30 ml/L to 40 ml/L H₂SO₄, 80 mg/L to 150 mg/L Cl⁻, 0.4 ml/L to 0.6 ml/L brightening agent, and 0.4 ml/L to 0.6 ml/L leveling agent, the cathode current density is 5 A/dm² to 10 A/dm², and the anode current density is 1 A/dm² to 2.5 A/dm².

13. The method of claim 5, wherein the heat dissipation layer is formed by painting heat dissipation paint on the copper layer.

14. The method of claim 13, wherein the heat dissipation paint includes a heat dissipation component, a film-forming component, and a solvent.

15. The method of claim 14, wherein the heat dissipation component is selected from the group consisting of boron nitride (BN), silicon carbon (SiC), aluminium nitride (AlN), and a combination thereof.

16. The method of claim 14, wherein the film-forming component is selected from the group consisting of aluminum oxide (Al₂O₃), silicon oxide (SiO₂), and a combination thereof.

17. The method of claim 14, wherein the solvent is selected from the group consisting of isopropyl alcohol, alcohol, deionized water, and a combination thereof.
